(19) United States
(12) Patent Application Publication
(10) Pub. No.: US 2023/0422641 A1
(43) Pub. Date: Dec. 28, 2023

(54) CMOS-COMPATIBLE RRAM DEVICES

(71) Applicant: TetraMem Inc., Fremont, CA (US)

(72) Inventors: Minxian Zhang, Amherst, MA (US); Mingche Wu, San Jose, CA (US); Ning Ge, Danville, CA (US)

(73) Assignee: TetraMem Inc., Fremont, CA (US)

(21) Appl. No.: 17/848,238

(22) Filed: Jun. 23, 2022

(51) Int. Cl. H01L 45/00; H01L 27/24

(52) U.S. Cl. CPC H01L 45/1253; H01L 27/2436; H01L 45/08; H01L 45/1233; H01L 45/146; H01L 45/16

(57) ABSTRACT

An apparatus including a CMOS-compatible resistive random-access memory (RRAM) devices is provided. The apparatus includes a transistor; one or more first interconnect layers fabricated on the transistor; an RRAM device fabricated on the one or more first interconnect layers; and one or more second interconnect layers fabricated on the RRAM device. The RRAM device includes: a bottom electrode; a switching oxide layer including a transition metal oxide; a top electrode; and one or more interface layer including a material that is more chemically stable than the transition metal oxide. In some embodiments, one or more diffusion barriers and/or adhesion layers are fabricated between the RRAM device and the first interconnect layers and/or between the RRAM device and the second interconnect layers.

### TECHNICAL FIELD

The implementations of the disclosure relate generally to resistive random-access memory (RRAM) devices and, more specifically, to CMOS (complementary metal-oxide semiconductor)-compatible RRAM devices and methods for fabricating the same.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, an apparatus including a CMOS-compatible RRAM is provided. The apparatus includes one or more first interconnect layers fabricated on a transistor. The apparatus further includes an RRAM device fabricated on the one or more first interconnect layers, where the RRAM device may include: a bottom electrode connected to a drain region of the transistor via the one or more first interconnect layers, where the bottom electrode is fabricated on a metal pad or a metal via of a top interconnect layer of the one or more first interconnect layers; a switching oxide layer may include at least one transition metal oxide; a top electrode; and a first interface layer fabricated between the top electrode and the switching oxide layer, where the first interface layer may include a first material that is more chemically stable than the at least one transition metal oxide. The apparatus includes one or more second interconnect layers fabricated on the RRAM device.

In some embodiments, the one or more first interconnect layers include a first via layer including a first plurality of metal vias. A first metal via of the first plurality of metal vias is connected to a source region of the transistor. A second metal via of the first plurality of metal vias is connected to a gate of the transistor. A third metal via of the first plurality of metal vias is connected to a drain region of the transistor. The bottom electrode of the RRAM device is connected to the drain region of the transistor via the third metal via.

In some embodiments, the first metal via is connected to a wordline. The second metal via is connected to a select line. The top electrode of the RRAM device is connected to a bitline.

In some embodiments, the one or more first interconnect layers further include a first metal layer comprising a plurality of metal pads, wherein the bottom electrode of the RRAM device is connected to the drain region of the transistor via one of the metal pads and the third metal via.

In some embodiments, the one or more second interconnect layers include a plurality of metal layers connected through one or more via layers, wherein each of the plurality of metal layers comprises one or more metal pads, wherein each of the via layers comprises one or more metal vias, and wherein a pair of neighboring metal layers of the plurality of metal layers are connected through one of the via layers.

In some embodiments, the first material includes at least one of Al₂O₃, MgO, Y₂O₃, or La₂O₃.

In some embodiments, the apparatus further includes a first diffusion barrier fabricated between the one or more first interconnect layers and the bottom electrode of the RRAM device.

In some embodiments, the first diffusion barrier includes at least one of TaN or TiN.

In some embodiments, the apparatus further includes a second diffusion barrier fabricated between the top electrode of the RRAM device and the one or more second interconnect layers.

In some embodiments, the second diffusion barrier includes at least one of TaN or TiN.

In some embodiments, the apparatus further includes a first adhesion layer fabricated between the one or more first interconnect layers and the first diffusion barrier. The first adhesion layer includes a layer of at least one of Ti, Ta, or Ti₄O₇.

In some embodiments, the apparatus further includes a second adhesion layer fabricated between the second diffusion barrier and the one or more second interconnect layers. The second adhesion layer includes a layer of at least one of Ti, Ta, or Ti₄O₇.

In some embodiments, the RRAM device further comprises a second interface layer fabricated between the bottom electrode of the RRAM device and the switching oxide layer of the RRAM device, wherein the second interface layer comprises a layer of a second material that is more chemically stable than the at least one transition metal oxide, wherein the second material comprises at least one of Al₂O₃, MgO, Y₂O₃, or La₂O₃.

In some embodiments, a method for fabricating an apparatus including a CMOS-compatible RRAM is provided. The method includes fabricating an RRAM device on one or more first interconnect layers; fabricating a bottom electrode on a metal via or a metal pad of a top interconnect layer of the one or more first interconnect layers; fabricating a switching oxide layer which may include at least one transition metal oxide; fabricating a first interface layer on the switching oxide layer; and fabricating one or more second interconnect layers on the RRAM device. The first interface layer may include a first material that is more chemically stable than the at least one transition metal oxide; and fabricating a top electrode on the first interface layer.

In some embodiments, fabricating the one or more second interconnect layers includes fabricating, on the RRAM device, a metal pad or a metal via of a bottom interconnect layer of the one or more second interconnect layers.

In some embodiments, fabricating the one or more second interconnect layers includes annealing the one or more second interconnect layers and the RRAM device in a forming gas.

In some embodiments, fabricating the one or more first interconnect layers includes fabricating a first via layer, wherein a first metal via of the first via layer is connected to a source region of a transistor, wherein a second metal via of the first via layer is connected to a gate of the transistor, and wherein a third metal via of the first via layer is connected to a drain region of the transistor, and wherein the bottom electrode of the RRAM device is connected to the drain region of the transistor through the third metal via.

In some embodiments, the methods further include fabricating a first diffusion barrier between the one or more first interconnect layers and the bottom electrode of the RRAM device, wherein the first diffusion barrier comprises at least one of TaN, Ta, or TiN.

In some embodiments, the methods further include fabricating a second diffusion barrier between the top electrode of the RRAM device and the one or more second interconnect layers, wherein the second diffusion barrier comprises at least one of TaN, Ta, or TiN.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1A is a schematic diagram illustrating an example of a crossbar circuit in accordance with some embodiments of the present disclosure.

FIG. 1B is a schematic diagram illustrating an example of a cross-point device in accordance with some embodiments of the present disclosure.

FIGS. 2A and 2B are schematic diagrams illustrating cross-sectional views of prior art integrated circuits.

FIGS. 3A and 3B are schematic diagrams illustrating cross-sectional views of example semiconductor devices including a CMOS-compatible RRAM in accordance with some embodiments of the present disclosure.

FIGS. 4A, 4B, 4C, 4D, 4E, and 4F are schematic diagrams illustrating cross-sectional views of example structures for fabricating a semiconductor device including a CMOS-compatible RRAM in accordance with some embodiments of the present disclosure.

FIGS. 5A and 5B are schematic diagrams illustrating cross-sectional views of example RRAM devices in accordance with some embodiments of the present disclosure.

FIGS. 6A, 6B, and 6C are schematic diagrams illustrating cross-sectional views of example RRAM devices in accordance with some embodiments of the present disclosure.

FIG. 7 is a flowchart illustrating example process for fabricating a semiconductor device including a CMOS-compatible RRAM in accordance with some embodiments of the present disclosure.

FIG. 8 is a flowchart illustrating an example process for fabricating interconnect layers in accordance with some embodiments of the present disclosure.

FIG. 9A is a flow chart illustrating an example process for fabricating an interconnect structure including a via layer and a metal layer in one process in accordance with some embodiments of the present disclosure.

FIGS. 9B, 9C, 9D, 9E, 9F, and 9G are schematic diagrams illustrating cross-sectional views of structures for fabricating an interconnect structure including a via layer and a metal layer in accordance with some embodiments of the present disclosure.

FIGS. 10A, 10B, and 10C are flowcharts illustrating example processes for fabricating an RRAM device in accordance with some embodiments of the present disclosure.

### DETAILED DESCRIPTION

Aspects of the disclosure provide CMOS-compatible resistive random-access memory (RRAM) devices and methods for fabricating the RRAM devices. An RRAM device is a two-terminal passive device with tunable resistance. The RRAM device may include a bottom electrode, a top electrode, and a switching oxide layer positioned between the bottom electrode and the top electrode. The bottom electrode may include a non-reactive metal, such as platinum (Pt), palladium (Pd), etc. The top electrode may include a reactive metal, such as tantalum (Ta), titanium (Ti), etc. The electrode including the non-reactive metal is also referred to herein as the “non-reactive electrode.” The electrode including the reactive metal is also referred to herein as the “reactive electrode.” The switching oxide layer may include a transition metal oxide, such as hafnium oxide (HfOₓ) or tantalum oxide (TaOₓ). The RRAM device may be in an initial state or virgin state and may have an initial high resistance before it is subject to a suitable electrical stimulation (e.g., a voltage or current signal applied to the RRAM device). The RRAM device may be tuned to a lower resistance state from the virgin state via a forming process or from a high-resistance state (HRS) to a lower resistance state (LRS) via a setting process. The forming process may refer to programming a device starting from the virgin state. The setting process may refer to programming a device starting from the high resistance state (HRS). After the reactive metal electrode is deposited on the switching oxide, the reactive metal can absorb oxygen from the switching oxide layer and create oxygen vacancies in the switching oxide layer, and oxygen ions can migrate in the switching oxide through a vacancy mechanism. During a forming process, a suitable programming signal (e.g., a voltage or current signal) may be applied to the RRAM device, which may cause a drift of oxygen ions to migrate from the switching oxide to the reactive electrode. As a result, a conductive channel or filament may form through the switching oxide layer (e.g., from the reactive electrode to the non-reactive electrode). The RRAM device may then be reset to a high-resistance state by applying a reset signal (e.g., a voltage signal, a current signal) to the RRAM device. The application of the reset signal to the RRAM device may cause oxygen to migrate back to the switching oxide layer and may thus interrupt the conductive filament. The RRAM device may be electrically switched between a high-resistance state and a low-resistance state by applying suitable programming signals (e.g., voltage signals, current signals, etc.) to the RRAM device. In a crossbar array circuit, the programming signals may be provided to the designated RRAM device via a selector, such as a transistor. It might be desirable to integrate RRAM arrays into CMOS circuits to implement high-density memory and/or computing applications.

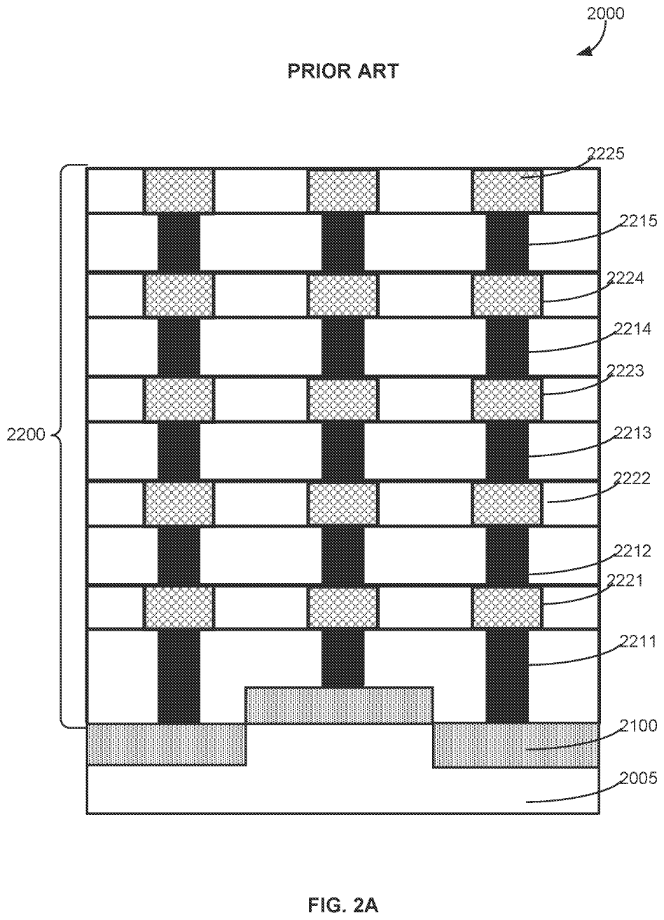

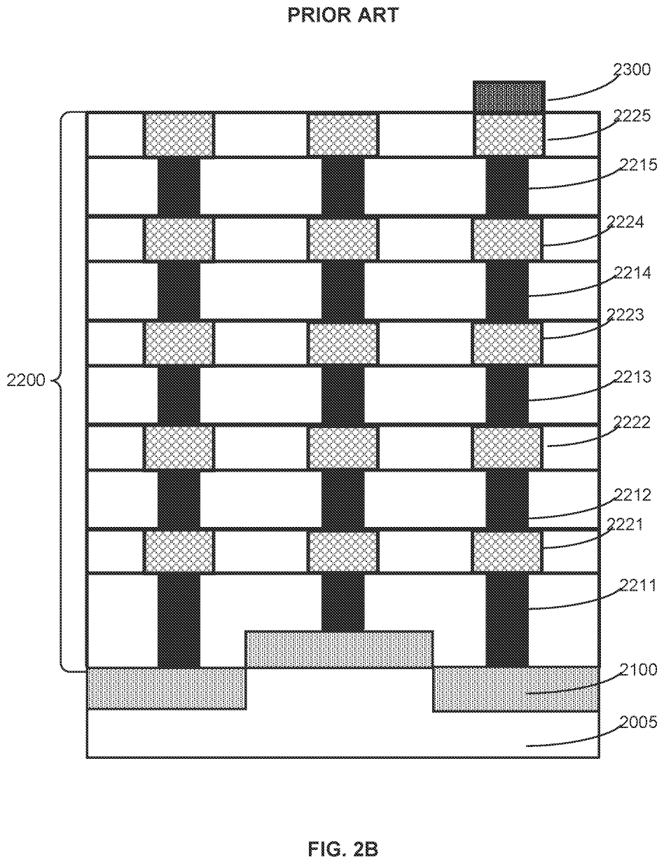

To implement a one-transistor-on-resistor (1T1R) configuration, a transistor (e.g., a complementary metal-oxide-semiconductor (CMOS)) and integrated circuits may be fabricated in a front-end-of-line (FEOL) process, and an RRAM device may be subsequently fabricated in a back-end-of-line (BEOL) process. The FEOL process may include fabricating transistors and multilayer metal interconnects. The BEOL process may include fabricating RRAM devices as arrays. As the RRAM devices are fabricated in the BEOL process after the FEOL or CMOS process, the fabrication of the RRAM devices does not have to be CMOS compatible. For example, as shown in FIG. 2A, an integrated circuit (IC) 2000 may include a transistor 2100 fabricated on a substrate 2005 and multiple interconnects 2200 fabricated on the transistor 2100. The transistor 2100 and the interconnects 2200 are fabricated in a CMOS process. The interconnects 2200 includes multiple via layers 2211, 2212, 2213, 2214, . . . , and 2215 and metal layers 2221, 2222, 2223, 2224, . . . , and 2225. Each of the via layers may include multiple metal vias. Each of the metal layers may include multiple metal pads and multiple metals wires (not shown). The metal vias and the metal pads are fabricated in the CMOS process. The dimensions of the metal vias and the metal pads may reduce sequentially from the metal layer 2225 towards the transistor 2100. For example, the IC 2000 may be part of a 65 nm technology node. Metal layer 2221 may have metal pads with width and spacing of 90 nm. Metal layers 2222 and 2223 may have metal pads with width and spacing of 100 nm. Metal layer 2225 may have metal pads with width and spacing of 400 nm. As such, the sizes of the inner interconnects that are located relatively closer to the transistor 2100 are significantly smaller than that of the interconnects that are located relatively further away from the transistor 2100.

As shown in FIG. 2B, an RRAM cell 2300 is fabricated on the top metal layer 2225 of the interconnects 2020. As such, the fabrication of the transistor 2010 and the interconnects 2020 and the fabrication of the RRAM device 2300 does not affect each other. However, the size of the RRAM cell 2300 is limited by the critical dimensions (CD) of the top metal pads, which are significantly greater than that of the metal pads of the inner interconnect layer located closer to the transistor 2100. Accordingly, fabricating RRAM cells on the top interconnect layers may prevent effective scaling down of the RRAM cells and may prevent effective increasing of the RRAM array density. It might be desirable to fabricate the RRAM cells on the inner interconnects to effectively scale down the RRAM cell sizes for high-density RRAM arrays during the CMOS process.

Fabricating the RRAM devices on the inner interconnect may enable the RRAM devices to be integrated as part of the CMOS process and require the RRAM devices to be CMOS compatible. There are several requirements for CMOS compatibilities, such as materials compatibilities and process compatibilities, etc. The materials compatibilities require the RRAM materials may not affect the CMOS materials and vice versa. The process compatibilities require the RRAM process may not affect the CMOS process and vice versa. For example, if an RRAM device is fabricated on an inner interconnect layer near a transistor, the metallization feature sizes, such as pitch sizes or line and spacing sizes, may be significantly reduced, which may benefit the device scaling down. However, an RRAM device fabricated on an inner interconnect layer may be subject to multiple metallization processes after it is fabricated. For example, each layer of Cu pads and vias may be fabricated with a Cu plating process and patterned with a dual damascene process. To reduce the Cu defects from plating, improve Cu metal's mechanical properties, and reduce Cu metal's electric resistance, each Cu layer may be involved in a forming gas annealing process. During the forming gas annealing (FGA) process, an interconnect is annealed at relatively high temperatures (e.g., 350-450° C.) in a forming gas flow (e.g., a mixture of N₂ and H₂) for 15-30 minutes. The forming gas annealing is a non-oxidizing environment with the presence of H₂ to prevent the oxidation of Cu during the annealing process. If an RRAM cell is fabricated on one of the inner layers, there could be several metallization layers fabricated after or above the RRAM device. As pointed out before, each metallization layer may require an FGA process, and an inner layer RRAM may be subject to multiple FGA processes. Therefore, new materials' stack may be necessary to protect the RRAM devices so their performance may not degrade during the CMOS fabrications, including the thermal stresses, chemical stresses, mechanical stresses, and other types of stresses on the RRAM cell during the CMOS fabrications. For example, the additional thermal exposure on the fabricated RRAM cell may increase the reaction between the switching oxide and the electrodes of the RRAM cell and may increase the diffusion of CMOS metals (Cu, Al, W, etc.) into the RRAM cell.

The present disclosure provides for mechanisms for fabricating CMOS-compatible RRAM devices on an inner interconnect layer. The RRAM devices may be fabricated utilizing CMOS compatible processes and may be resistant to annealing stresses released during the subsequent fabrication of interconnects on the RRAM devices.

In some embodiments, an RRAM device in accordance with the present disclosure may be fabricated on one or more first interconnect layers. One or more second interconnect layers may be fabricated on the RRAM device without deteriorating the performance of the RRAM device. The RRAM device may include a bottom electrode, a switching oxide layer, a top electrode, one or more interface layers, one or more diffusion barriers, and one or more adhesion layers. The switching oxide layer may include a transition metal oxide, such as TaOₓ, HfOₓ, TiOₓ, NbOₓ, ZrOₓ, etc. Each of the interface layers may include a layer of a material that is more chemically stable than the transition metal oxide, such as Al₂O₃. In one implementation, an interface layer may be fabricated between the top electrode and the switching oxide layer. In another implementation, the RRAM device may further include an interface layer fabricated between the bottom electrode and the switching oxide layer. The interface layer(s) may enable the RRAM device to resist the stresses released from the subsequent fabrication processes of the interconnect layers (e.g., metallization and annealing processes for fabricating the interconnect layers on the RRAM device). Thus, the RRAM device is CMOS-compatible as it may be fabricated in a CMOS process. The RRAM device is annealing resistant and may be fabricated on an inner interconnect layer.

In some embodiments, one or more diffusion barriers (e.g., layers of Ta, TaN, and/or TiN) may be fabricated between the RRAM device and the interconnect layers, which may include metal pads or metal vias, adjacent to the RRAM device to further enhance the annealing resistance of the RRAM device and to prevent metals in the interconnect layers (e.g., Cu, Al, W) from diffusing into the RRAM device. For example, a first diffusion barrier may be fabricated between the one or more first interconnect layers and the bottom electrode of the RRAM device. Additionally or alternatively, a second diffusion barrier may be fabricated between the second one or more interconnect layers and the top electrode of the RRAM device.

In some embodiments, one or more adhesion layers may be fabricated between the RRAM device and the interconnect layers adjacent to the diffusion barrier layers to further enhance the adhesion between the RRAM device and adjacent CMOS metallization. The adhesion layers may be and/or include one or more layers of Ti, Ta, W, Ti₄O₇, etc. Ti₄O₇ is a suboxide of TiO₂ and may exhibit metallic conductivity. As an example, a first adhesion layer may be fabricated between the one or more first interconnect layers and the first diffusion barrier layer and/or the bottom electrode of the RRAM device. Additionally or alternatively, a second adhesion layer may be fabricated between the one or more second interconnect layers and the second diffusion barrier layer and/or the top electrode of the RRAM device.

Accordingly, the present disclosure provides mechanism for fabricating RRAM devices using CMOS compatible processes. By fabricating the RRAM devices on the inner interconnects having relatively smaller sizes, the mechanisms described herein may enhance the scalability of a crossbar array of RRAM devices and may enable high-density memory and/or computing applications.

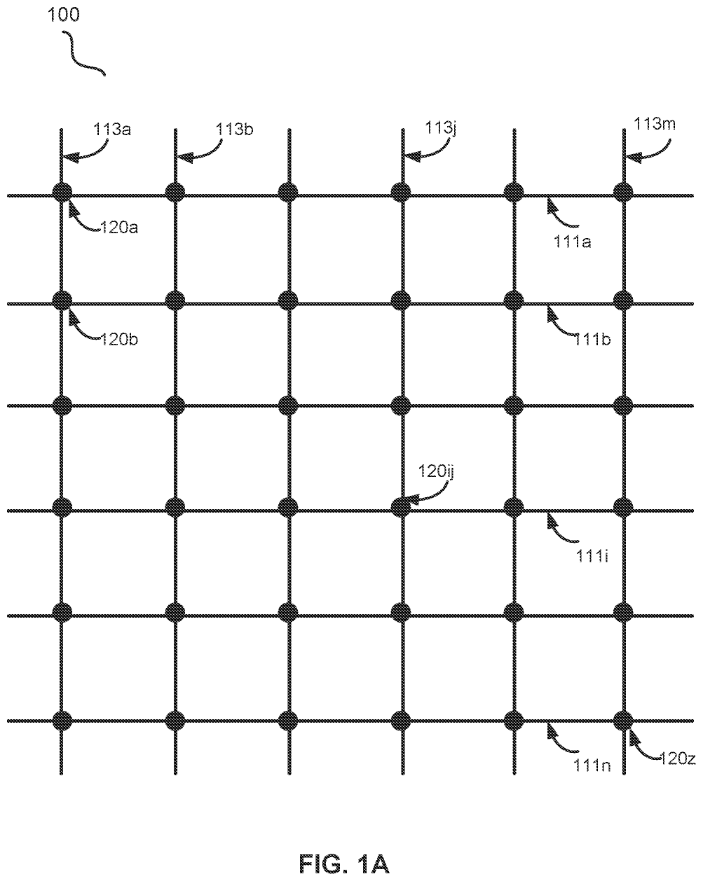

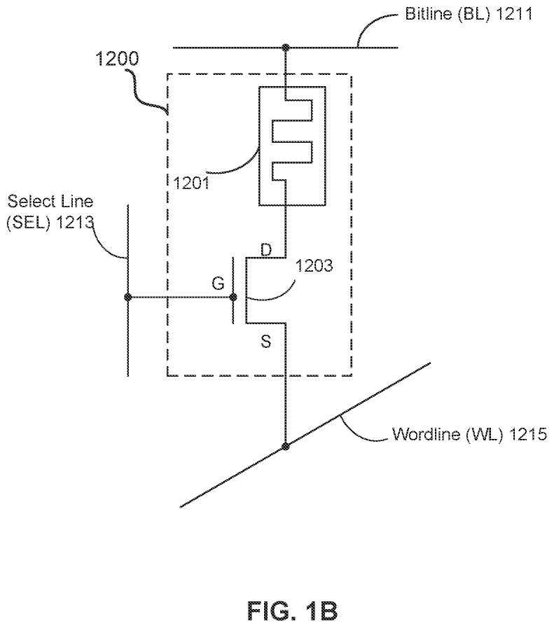

FIG. 1A is a schematic diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111 may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-n may be a metal wire.

Column wires 113 may include a first column wire 113a, a second column wire 113b, . . . , and an m-th column wire 113m. Each of column wires 113a-m may be and/or include any suitable electrically conductive material. In some embodiments, each column wire 113a-m may be a metal wire.

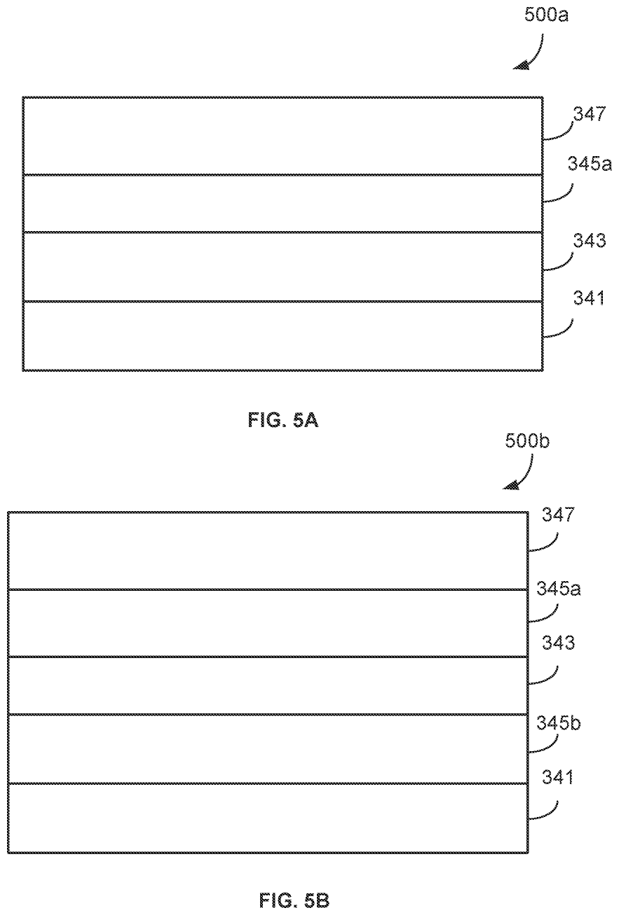

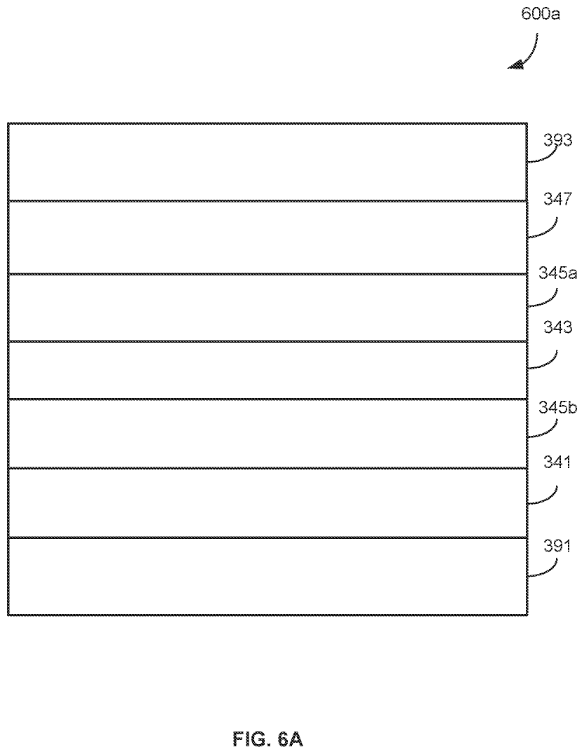

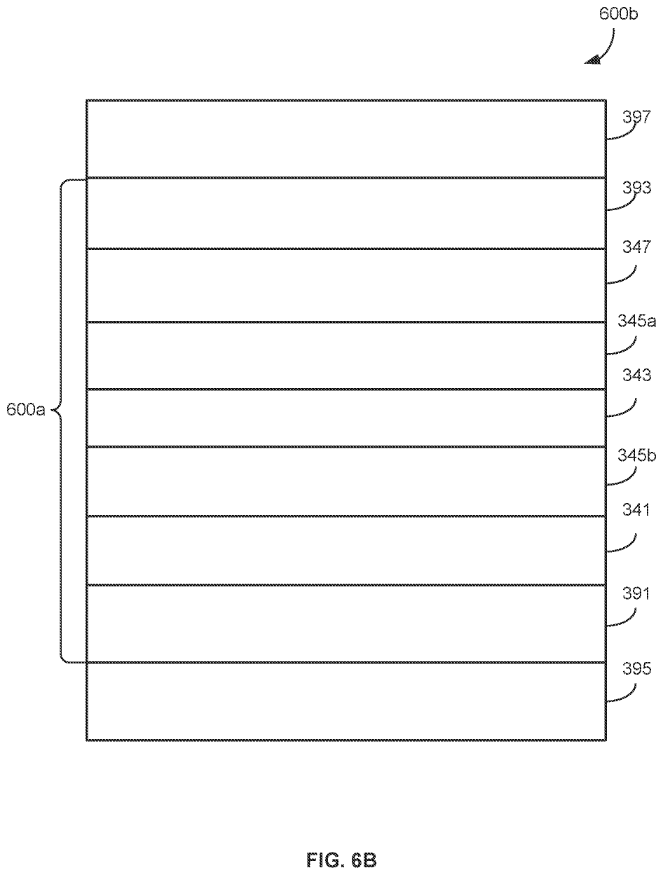

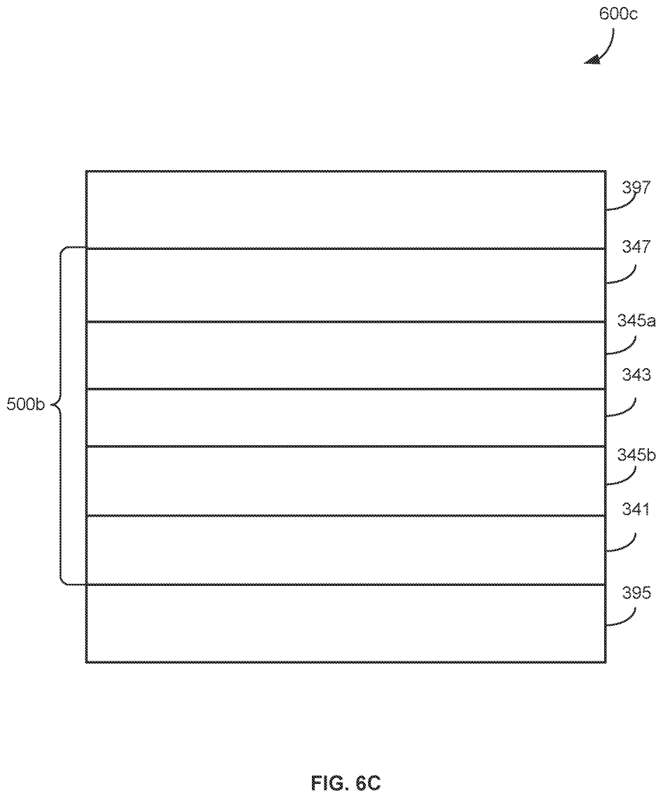

Each cross-point device 120 may be and/or include any suitable device with tunable resistance, such as a memristor, phase-change memory (PCM) devices, floating gates, spintronic devices, resistive random-access memory (RRAM), static random-access memory (SRAM), etc. In some embodiments, one or more of cross-point devices 120 may include an RRAM device and a transistor as described in connection with FIGS. 5A-6C.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is outputted via each column wire and may be accumulated according to Kirchhoff's current law. This may enable in-memory computing (IMC) via parallel multiplications and summations performed in the crossbar arrays.

FIG. 1B is a schematic diagram illustrating an example 1200 of a cross-point device in accordance some embodiments of the present disclosure. As shown, cross-point device 1200 may connect a bitline (BL) 1211, a select line (SEL) 1213, and a wordline (WL) 1215. The bitline 1211 and the wordline 1215 may be a column wire and a row wire as described in connection with FIG. 1A, respectively.

Cross-point device 1200 may include an RRAM device 1201 and a transistor 1203. A transistor is a three-terminal device, which may be marked as gate (G), source (S), and drain (D), respectively. The transistor 1203 may be serially connected to RRAM device 1201. As shown in FIG. 1B, the bottom electrode of the RRAM device 1201 may be connected to the drain of transistor 1203. The top electrode of the RRAM device 1201 may be connected to the bitline 1211. The source of the transistor 1203 may be connected to the wordline 1215. The gate of the transistor 1203 may be connected to the select line 1213. RRAM device 1201 may include one or more RRAM devices as described in connection with FIGS. 2A-5M below. Cross-point device 1200 may also be referred to as in a 1-transistor-1-resistor (1T1R) configuration. The transistor 1203 may perform as a selector as well as a current controller, which may set the current compliance, to the RRAM device 1201 during programming. The gate voltage on transistor 1203 can set current compliances to cross-point device 1200 during programming and can thus control the conductance and analog behavior of cross-point device 1200. For example, when cross-point device 1200 is set from a high-resistance state to a low-resistance state, a set signal (e.g., a voltage signal, a current signal) may be provided via the bitline (BL) 1211. Another voltage, also referred as a select voltage or gate voltage, may be applied via the select line (SEL) 1213 to the transistor gate to open the gate and set the current compliance, while the wordline (WL) 1215 may be set to ground. When cross-point device 1200 is reset from the low-resistance state to the high-resistance state, a gate voltage may be applied to the gate of the transistor 1203 via the select line 1213 to open the transistor gate. Meanwhile, a reset signal may be sent to the RRAM device 1201 via the wordline 1215, while the bitline 1211 may be set to ground.

FIGS. 2A and 2B are schematic diagrams illustrating cross-sectional views of prior art integrated circuits (ICs). The ICs may be fabricated in a CMOS process for fabricating interconnects 2200, and a CMOS process for fabricating interconnects 2200 and an RRAM 2300 in a 1T1R configuration, respectively. The advantages and disadvantages of the RRAM process 2300 after CMOS process 2200 are described above. It is to be noted that each metal layer 2221, 2222, . . . , and 2225 may include meta wires (no shown). The RRAM device 2300 is shown as a block which may include, for example, a bottom electrode, a switching oxide layer, and a top electrode.

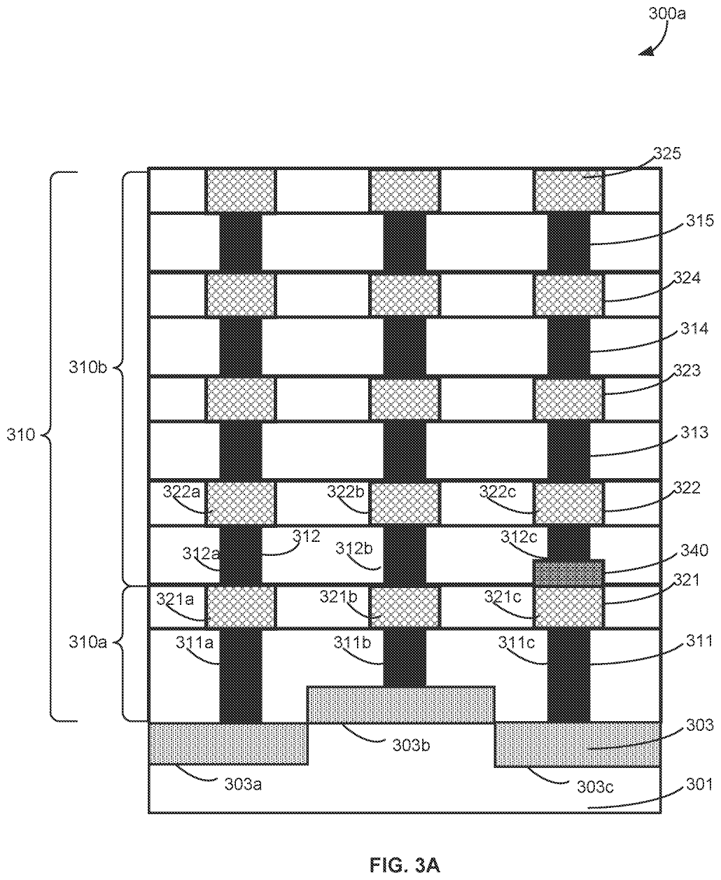

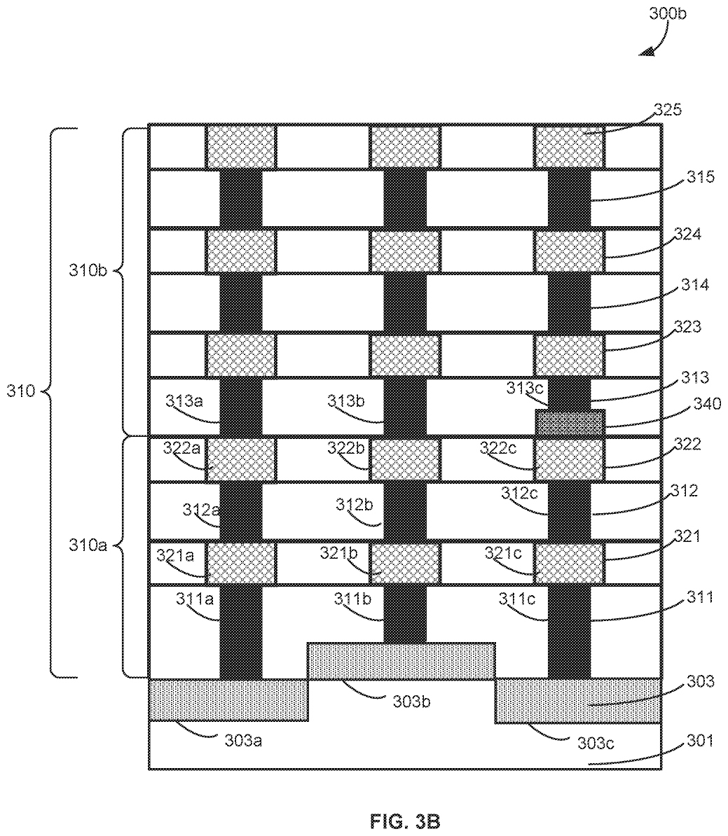

FIGS. 3A and 3B are schematic diagrams illustrating cross-sectional views of example semiconductor devices 300a and 300b including a CMOS-compatible RRAM in accordance with some embodiments of the present disclosure.

As shown, a transistor 303 is fabricated on a substrate 301. The transistor 303 may include a source region 303a, a gate 303b, and a drain region 303c. While one transistor is shown in FIG. 3A, this is merely illustrative. Multiple transistors (not shown) may be fabricated on the substrate 301 in some embodiments. The transistors may be isolated by suitable insulator and/or dielectric material.

The semiconductor device 300a may include interconnect layers 310 fabricated on the transistor 303 and the substrate 301. Each of the interconnect layers 310 may provide electrical connectivity between the transistor 303 and/or one or more other devices (e.g., one or more other transistors, one or more other RRAM devices, etc.). The interconnect layers 310 may include, for example, via layers (or via layers) 311, 312, 313, 314, 315, and 316 and metal layers (or pad layers) 321, 323, 324, 325, and 326. Each of the via layers may include one or more metal vias. Each of the metal vias may include a suitable metallic material, such as Al, Cu, W, etc. Each of the metal layers may include one or more metal pads. Each of the metal pads may include a suitable metallic material, such as Al, Cu, W, etc. For example, the via layer 311 may include metal vias 311a, 311b, and 311c that may be connected to the source region 303a, the gate 303b, and the drain region 303c of the transistor 303, respectively. In some embodiments, the via layer 311 may include tungsten (W) vias and doped polycrystalline Si (poly-Si) terminals where poly-Si terminals may be in direct contact to the gate 303b, the source region 303a, and the drain region 303c of the transistor 303. The tungsten vias may be in direct contact to the poli-Si terminals. The other via layers and metals layers above the via layer 311 may be fabricated with Cu, W, Al, etc. The metal layer 321 may include metal pads 321a, 321b, and 321c. The metal pads 321a, 321b, and 321c may be connected to the metal vias 311a, 311b, and 311c, respectively.

As shown, a pair of neighboring metal layers may be connected via a via layer fabricated between the neighboring metal layers. For example, a first metal layer 321 may be connected to a second metal layer 322 through a via layer 312. In particular, the metal pad 322a of the metal layer 322 may be connected to the metal pad 321a of the metal layer 321 through the metal via 312a. The metal pad 322b of the metal layer 322 may be connected to the metal pad 321b of the metal layer 321 through the metal via 312b. The metal pad 322c of the metal layer 322 may be connected to the metal pad 321c of the metal layer 321 through the metal via 312c.

The interconnect layers 310 may have varying dimensions. The sizes of the metal pads of the metal layers 321, 322, 323, 324, 325, . . . , 326 may increase sequentially. Similarly, the sizes of the metal via in the via layers 311, 312, 313, 314, 315, . . . , 316 may increase sequentially. For example, the semiconductor device 300 may be part of a 65 nm technology node. The width and the spacing of the metal pads of the metal layer 321 may be about 90 nm. The width and the spacing of the metal pads of the metal layers 322 and 323 may be about 100 nm. The width and the spacing of the metal pads of the metal layers 326 may be about 400 nm.

An RRAM device 340 may be fabricated during the fabrication of the interconnect layers 310. As such, the RRAM device 340 is referred to as a CMOS-compatible RRAM device. For example, one or more first interconnect layers 310a may be fabricated on the transistor 303 and/or the substrate 301. The RRAM device 340 may be fabricated on a metal pad or a metal via of the top interconnect layer of the first interconnect layers 310a. One or more second interconnect layers 310b may then be fabricated on the RRAM device 340 and the first interconnect layers 310a. More particularly, for example, a metal pad or metal via of the bottom interconnect layer of the second interconnect layers 310b may be fabricated on the RRAM device 340 and may directly contact the RRAM device 340. In some embodiments, as shown in FIG. 3A, the first interconnect layers 310a may include the via layer 311 and the metal layer 321. The metal layer 321 may be regarded as being the top interconnect layer of the first interconnect layers 310a. The RRAM device 340 may be fabricated on the metal pad 321c of the metal layer 321. The RRAM device 340 is connected to the drain region 303c of the transistor 303 through the metal pad 321c of the metal layer 321 and the metal via 311c of the via layer 311. The metal via 312c of the via layer 312 may be fabricated on the RRAM device 340 and may be connected to a bitline of a circuit including the RRAM device 340 (e.g., the bitline 1211 of FIG. 1B). The metal vias 312a and 312b of the via layer 312 may be fabricated on the metal pads 321a and 321b, respectively. The metal layer 312 may be regarded as being the bottom interconnect layer of the second interconnect layers 310b. The second interconnect layers 310b may include one or more metal layers and/or via layers fabricated on the metal layer 312 (e.g., metal layers 322, 323, 324, and 325 and via layers 313, 314, and 315).

In some embodiments, as shown in FIG. 3B, the RRAM device 340 may be fabricated on the metal pad 322c of the metal layer 322. The via layer 313 may be fabricated on the RRAM device 340. In particular, the metal via 313c of the via layer 313 is fabricated on the RRAM device 340 and directly contact the RRAM device 340. In such embodiments, the first interconnect layers may include the via layer 311, the metal layer 321, the via layer 312, and the metal layer 322. The metal layer 322 may be regarded as being the top interconnect layer of the first interconnect layers 310a. The second interconnect layers 310b may include the via layers 313, 314, and 315 and the metal layers 323, 324, and 325. The via layer 313 may be regarded as the bottom interconnect layer of the second interconnect layers 310b.

Although the total processing steps involved in fabricating the interconnect layers 310 in FIGS. 3A and 3B may be the same, fabricating the first interconnect layers 310a in FIG. 3B includes more steps than fabricating the first interconnect layers 310a in FIG. 3A, while fabricating the second interconnect layers 301b in FIG. 3B includes fewer steps than fabricating the second interconnect layers 310b in FIG. 3A. The RRAM device 340 is connected to the drain region 303c of the transistor 303 through the metal pad 322c of the metal layer 322, the metal via 312c of the via layer 312, the metal pad 321c of the metal layer 321, and the metal via 311c of the via layer 311. Metal via 313c of the via layer 313 may be fabricated on the RRAM device 340 and may be connected to the bitline of the circuit (e.g., the bitline 1211 of FIG. 1B). Metal vias 313a and 313b of the via layer 313 may be fabricated on the metal pads 322a and 322b, respectively.

While certain interconnect layers (e.g., metal layers and via layers) are shown in FIGS. 3A-3B, this is merely illustrative. The semiconductor device 300a may include any suitable number of interconnect layers for implementing various integrated circuits. The first interconnect layers 310a and the second interconnect layers 310b may include any suitable number of interconnect layers. For example, the RRAM device 340 may be fabricated on the metal layer 323 in some embodiments.

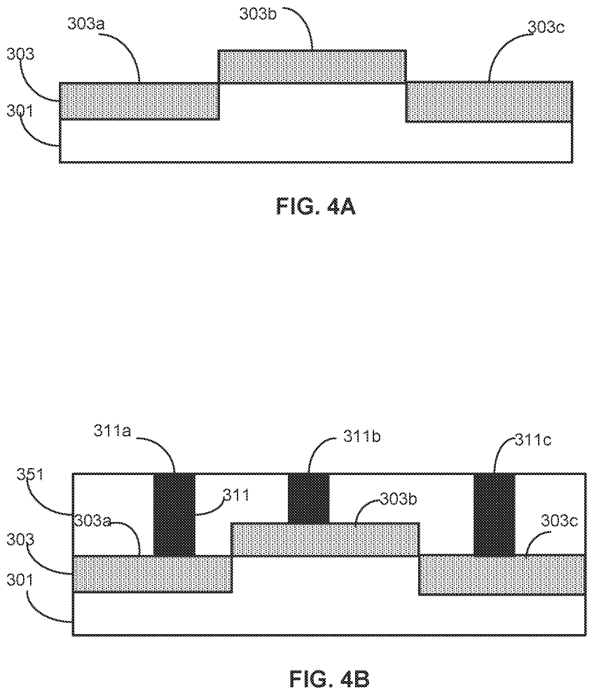

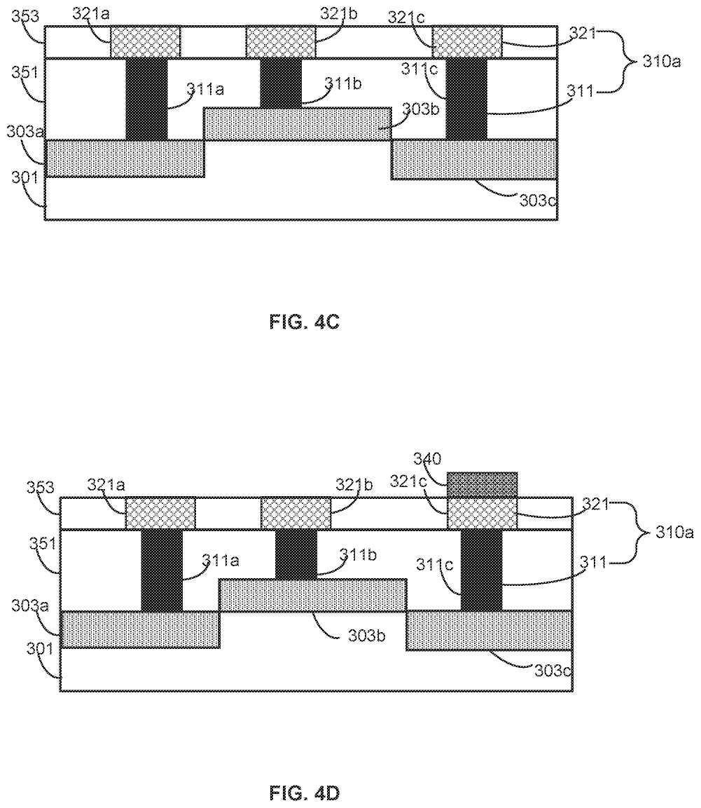

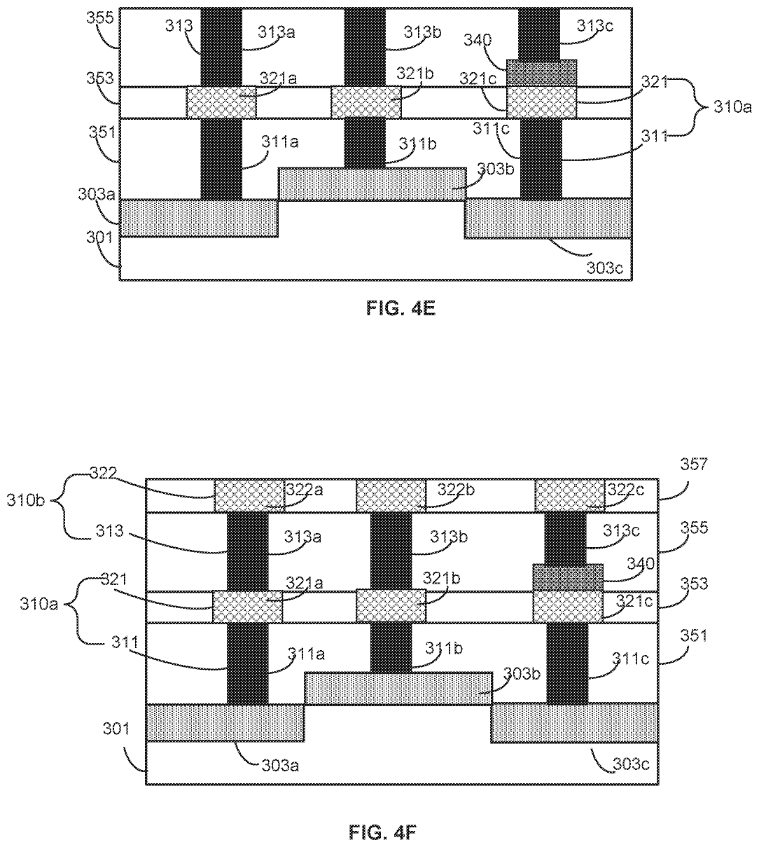

FIGS. 4A-4F are schematic diagrams illustrating cross-sectional views of example structures for fabricating a semiconductor device including a CMOS-compatible RRAM in accordance with some embodiments of the present disclosure.

As shown in FIG. 4A, the transistor 303 is fabricated on the substrate 301. As shown in FIG. 4B, a first via layer 311 may be fabricated on the transistor 303 and the substrate 301. The first via layer 311 may include one or more metal vias, such as metal vias 311a, 311b, and 311c. Each of the metal vias 311a, 311b, and 311c may be and/or include one or more poly-Si terminals connected to the transistor terminals and W metal vias connected to the poli-Si terminals. The metal vias 311a, 311b, and 311c may be connected to the source region 303a, the gate 303b, and the drain region 303c of the transistor, respectively. The metal via 311b may also be referred to as the CB as it directly contacts the gate region of the transistor. The metal vias 311a and 311c may also be referred to as CA as they directly contact the source region and the drain region of the transistor. To fabricate the first via layer 311, a dielectric layer 351 may be fabricated on the substrate 301 and the transistor 303. The dielectric layer 351 may include any suitable dielectric material, such as silicon nitride (Si₃N₄), silicon dioxide (SiO₂), etc. The dielectric layer 351 may be processed utilizing any suitable deposition techniques. For example, the dielectric layer 351 may be patterned and filled by metal deposition to fabricate the metal vias 311a, 311b, and 311c in the dielectric layer 351.

As shown in FIG. 4C, a first metal layer 321 may be fabricated and patterned on the first via layer 311. The first metal layer 321 may include one or more metal pads, such as a first metal pad 321a, a second metal pad 321b, and a third metal pad 321c. The first metal pad 321a may be connected to the source region 303a through the metal via 311a. The second metal pad 321b may be connected to the gate 303b through the metal via 311b. The third metal pad 321c may be connected to the drain region 303c through the metal via 311c. In some embodiments, the first metal pad 321a may be connected to a wordline (e.g., the wordline 1215 of FIG. 1B). The second metal pad 321b may be connected to a select line (e.g., the select line 1213 of FIG. 1B). The via layer 311 and the metal layer 321 may be referred to as the first interconnect layers 310a in this implementation.

To fabricate the first metal layer 321, a dielectric layer 353 may be fabricated on the dielectric layer 351 and the first via layer 311. The dielectric layer 353 may include any suitable dielectric material, such as Si₃N₄. SiO₂, etc. The dielectric layer 353 may be processed utilizing any suitable deposition techniques and may be patterned. The first metal layer 321 may then be fabricated by depositing suitable metallic materials (e.g., Cu, Au, W, etc.) in the patterned dielectric layer 253 and be patterned to fabricate the metal pads 321a, 321b, and 321c.

As shown in FIG. 4D, an RRAM device 340 may be fabricated on the metal pad 321c. The RRAM device 340 may include a bottom electrode, a switching oxide layer, and a top electrode, and one or more interface layers, as shown in FIGS. 5A-5B. For example, an interface layer may be fabricated between the top electrode and the switching oxide layer. Additionally, an interface layer may be fabricated between the bottom electrode and the switching oxide layer. The interface layer(s) may enable the RRAM device to resist the stresses released from the subsequent fabrication processes of the one or more second interconnect layers (e.g., metallization process and annealing processes for fabricating interconnects on the RRAM device). Thus, the RRAM device is annealing resistant and CMOS compatible and may be fabricated on an inner interconnect of the interconnect layers. In some embodiments, the RRAM device 340 may include one or more diffusion barriers (e.g., layers of TaN and/or TiN) to further enhance the annealing resistance of the RRAM device and to prevent metals in the interconnect layers (e.g., Cu, Al, W) from diffusing into the RRAM device 340. In some embodiments, one or more adhesion layers (e.g., layers of Ti, Ta, and/or Ti₄O₇) may be fabricated between the RRAM device 340 and the interconnect layers adjacent to the diffusion barrier layers to further enhance the adhesion between the RRAM device and adjacent CMOS metallization. The RRAM device may be and/or include RRAM devices 500a, 500b, 600a, 600b, and/or 600c of FIGS. 5A-6C.

One or more second interconnect layers 310b may be fabricated on the RRAM device 340 and the first interconnect layers 310a. For example, as shown in FIG. 4E, a dielectric layer 355 may be fabricated on the RRAM device 340 and the metal layer 321. A via layer 313 may be fabricated by pattering the dielectric layer 355 and depositing suitable metallic material in the patterned dielectric layer 355. The via layer 313 may include metal vias 313a, 313b, and 313c. The metal vias 313a, 313b, and 313c may be connected to the metal pads 321a, 321b, and the RRAM device 340, respectively. In some embodiments, the metal vias 313a, 313b, and 313c directly contact the metal pads 321a, 321b, and the RRAM device 340, respectively. In some embodiments, the RRAM device 340 may be fabricated on one of the metals vias connected to the drain terminal of the transistor.

A dielectric layer 357 may be fabricated on the dielectric layer 355 and the via layer 313. A metal layer 322 may be fabricated by pattering the dielectric layer 357 and depositing suitable metallic material in the patterned dielectric layer 357 and be patterned. The metal layer 322 may include metal pads 322a, 322b, and 322c. The metal pads 322a, 322b, and 322c may connect to the metal vias 313a, 313b, and 313c, respectively.

While certain interconnect layers are illustrated in FIGS. 4A-4F, this is merely illustrative. The one or more first interconnect layers 310a and the one or more second interconnect layers 310b may include any suitable number of interconnect layers as described herein. For example, one or more metal layers and/or via layers (not shown) may be fabricated on the metal pads 322a, 322b, and 322c. As another example, one or more metal layers and/or via layers (not shown) may be fabricated between the RRAM device 340 and the metal layer 321.

FIGS. 5A and 5B are schematic diagrams illustrating cross-sectional views of example RRAM devices 500a and 500b in accordance with some embodiments of the present disclosure.

As shown in FIG. 5A, the RRAM device 500a may include a bottom electrode 341, a switching oxide layer 343, an interface layer 345a, and a top electrode 347. The interface layer 345a (also referred to as the “interface layer A” or the “first interface layer”) is fabricated between the top electrode 347 and the switching oxide layer 343.

The switching oxide layer 343 may include one or more transition metal oxides, such as TaOₓ, HfOₓ, TiOₓ, NbOₓ, ZrOₓ, etc., in binary oxides, ternary oxides, and high order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). As an example, the switching oxide layer 343 may include Ta₂O₅. As the other example, the switching oxide layer 343 may include HfO₂.

The interface layer 345a may be and/or include a film of a first material that is more chemical stable than the transition metal oxide(s) in the switching oxide layer 343. As a result, the first material may not react with the transition metal oxide(s) of the switching oxide layer 343. As an example, the transition metal oxide(s) of the switching oxide layer may be and/or include one or more transition metal oxides, such as at least one of HfOₓ or TaO_{y}, wherein x≤2.0, and wherein y≤2.5, and the first material may include Al₂O₃, MgO, Y₂O₃, La₂O₃, etc.

The interface layer 345a may prevent excessive reaction between RRAM switching oxide and the electrodes caused by additional thermal exposure to the RRAM device during the subsequent fabrication of interconnect layers on the RRAM device 340.

The interface layer 345a may have a suitable thickness to achieve desirable forming gas anneal (FGA) resistance. For example, a relatively thicker interface layer may be more FGA resistant than a relatively thinner interface layer. In one implementation, the interface layer 345a may include a discontinuous film of Al₂O₃, SiO₂, Y₂O₃, etc. In another implementation, the interface layer 345a may include a continuous film of Al₂O₃, SiO₂, Y₂O₃, La₂O₃, etc.

In some embodiments, as illustrated in FIG. 5B, an RRAM 500b device may include multiple interface layers. For example, an interface layer 345b (also referred to as the “interface layer B” or the “second interface layer”) may be fabricated between the bottom electrode 341 and the switching oxide layer 343. The interface layer 345b may be and/or include a film of a second material that is more chemical stable than the transition metal oxide(s) in the switching oxide layer 343. As a result, the second material may not react with the transition metal oxide(s) of the switching oxide layer 343. As an example, the transition metal oxide(s) of the switching oxide layer may be and/or include one or more transition metal oxides, such as at least one of HfOₓ or TaO_{y}, wherein x≤2.0, and wherein y≤2.5, and the second material may include Al₂O₃, MgO, Y₂O₃, La₂O₃, etc. The first material in the interface layer 345a may or may not be the same as the second material in the interface layer 345b. The interface layer 345 may also be useful where metal nitride being used as the bottom electrode.

The interface layer 345b may have a desired thickness to achieve desirable FGA resistance. For example, a relatively thicker interface layer may be more FGA resistant than a relatively thinner interface layer. In one implementation, the interface layer 345b may include a discontinuous film of Al₂O₃, SiO₂, Y₂O₃, etc. In another implementation, the interface layer 345b may include a continuous film of Al₂O₃, SiO₂, Y₂O₃, etc.

FIGS. 6A and 6B are schematic diagrams illustrating cross-sectional views of example RRAM devices 600a and 600b in accordance with some embodiments of the present disclosure.

As shown in FIG. 6A, the RRAM device 600a may include a first diffusion barrier 391, a bottom electrode 341, an interface layer 345b, a switching oxide layer 343, an interface layer 345a, a top electrode 347, and a second diffusion barrier 393. The bottom electrode 341, the interface layer 345b, the switching oxide layer 343, the interface layer 345a, and the top electrode 347 may be the same as their counterparts as described in connection with FIGS. 5A-5B above. The first diffusion barrier 391 may be fabricated between the top interconnect layer of the one or more first interconnect layers 310a of FIGS. 3A-3B (not shown in FIG. 6A) and the bottom electrode 341. The second diffusion barrier 393 may be fabricated between the top electrode 347 and the bottom interconnect layer of the second interconnect layers 310b of FIGS. 3A-4F (not shown in FIG. 6A).

The first diffusion barrier 391 and the second diffusion barrier 393 may include any suitable material that may prevent metals in the interconnect layers from diffusing into the RRAM device at annealing temperatures and may exhibit suitable thermal and chemical stability, conductivity, and adhesion. In some embodiments, the first diffusion barrier 391 and/or the second diffusion barrier 393 may include one or more layers of TaN, TiN, etc.

The first diffusion barrier 391 and/or the second diffusion barrier 393 may further enhance the annealing resistance of the RRAM device and prevent metals in the interconnects (e.g., Cu, Al, W) from diffusing into the RRAM device 340.

In some embodiments, one or more adhesion layers may be fabricated between the RRAM device 600a and the interconnect layers. For example, as shown in FIG. 6B, the RRAM device 600a may be fabricated on a first adhesion layer 395. The first adhesion layer 395 may be fabricated on the top interconnect layer of the first interconnect layers 310a of FIGS. 3A-3B (not shown in FIG. 6B).

A second adhesion layer 397 may be fabricated on the RRAM device 600a and/or the second diffusion barrier 393. One or more second interconnect layers 310b of FIGS. 3A-4F (not shown in FIG. 6B) may be fabricated on the second adhesion layer 397. Each of the first adhesion layer 395 and the second adhesion layer 397 may include one or more layers of Ti, Ta, or conductive oxide such as Ti₄O₇, etc.

In some embodiments, the first diffusion barrier 391 and/or the second diffusion barrier 393 may be omitted from RRAM 600b. For example, as shown in FIG. 6C, RRAM device 600c may include the RRAM device 500b fabricated on the first adhesion layer 395. The second adhesion layer 397 may be fabricated on the top electrode 347.

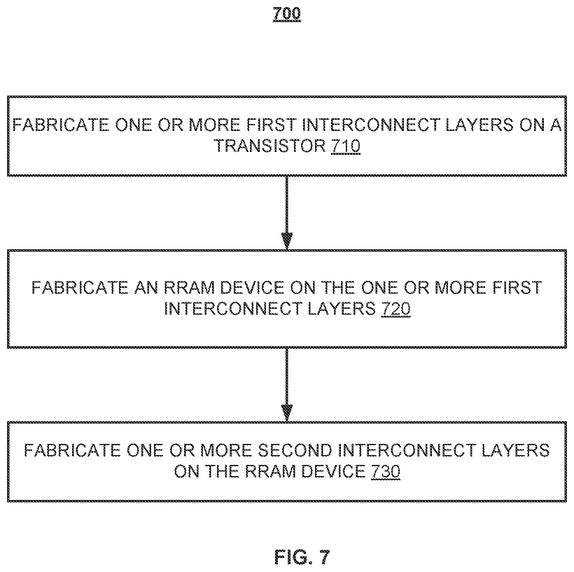

FIG. 7 is a flowchart illustrating example process 700 for fabricating a semiconductor device including a CMOS-compatible RRAM in accordance with some embodiments of the present disclosure.

As shown, process 700 may start at 710 where one or more first interconnect layers may be fabricated on a transistor. The transistor may include a source region, a gate, and a drain region. The transistor may be fabricated on a substrate as described in connection with FIG. 4A. Each of the first interconnect layers may include one or more metal pads and/or metal vias as described herein. A pair of neighboring metal layers may be connected via a via layer fabricated between the neighboring metal layers.

In some embodiments, fabricating the one or more first interconnect layers may involve fabricating a first via layer including a first plurality of metal vias (e.g., the first via layer 311 of FIG. 4B). Fabricating the first via layer may include fabricating a first dielectric layer of a first dielectric material (e.g., the dielectric layer 351 of FIG. 4B) and processing the first dielectric layer utilizing suitable deposition and patterning techniques. For example, the first dielectric layer may be patterned and filled by metal deposition to fabricate the plurality of metal vias (e.g., the metal vias 311a, 311b, and 311c in FIG. 4B). A first metal via, a second metal via, and a third via of the first via layer may be connected to a source region, a gate, and a drain region of the transistor, respectively.

In some embodiments, fabricating the one or more first interconnect layers may further involve fabricating a first metal layer (e.g., the first metal layer 321 of FIG. 4C) on the first via layer. The first metal layer may include a first plurality of metal pads (e.g., the metal pads 321a, 321b, and 321c of FIG. 4C). In some embodiments, a first metal pad of the first metal layer (e.g., the metal pad 321a) may directly contact a first metal via of the first via layer (e.g., the metal via 311a). A second metal pad of the first metal layer (e.g., the metal pad 321b) may directly contact a second metal via of the first via layer (e.g., the metal via 311b). A third metal pad of the first metal layer (e.g., the metal pad 321c) may directly contact a third metal via of the first via layer (e.g., the metal via 311c).

In some embodiments, fabricating the one or more first interconnect layers may further involve fabricating a second via layer on the first metal layer. The second via layer may include a second plurality of metal vias. Each of the second plurality of metal vias may directly contact a respective metal contact of the first plurality of metal contacts of the first metal layer.

In some embodiments, fabricating the one or more first interconnect layers may further involve fabricating a second metal layer on the second via layer. The second metal layer may include a second plurality of metal pads. Each of the second plurality of metal pads may directly contact a respective metal via of the second via layer.

In one implementation, the one or more first interconnect layers only includes the first via layer. In another implementation, the one or more first interconnect layers includes the first via layer, the first metal layer, the second via layer, and the second metal layer. In a further implementation, the one or more first interconnect layers includes the first via layer, the first metal layer, and the second via layer.

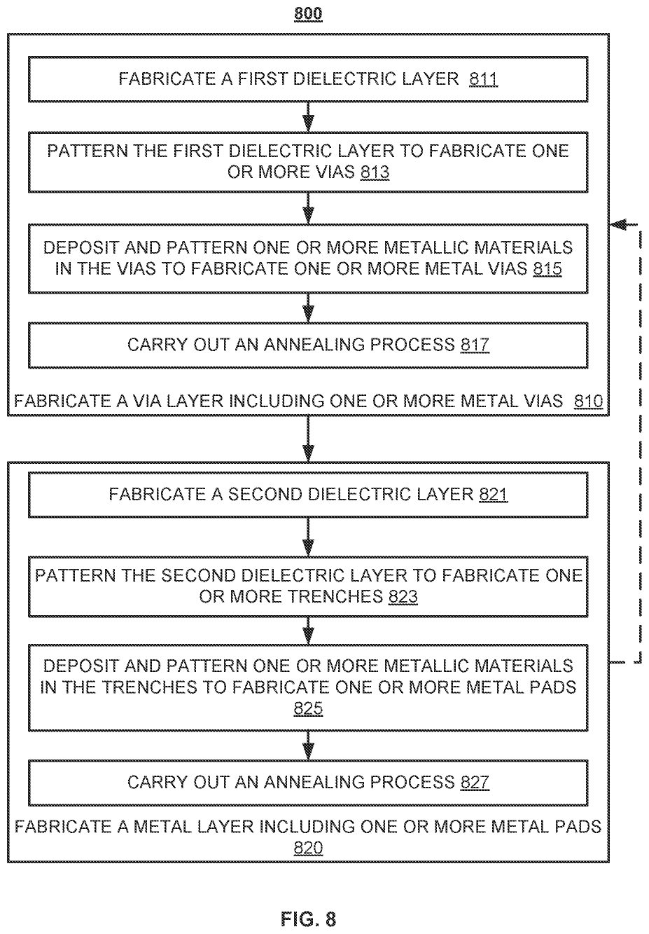

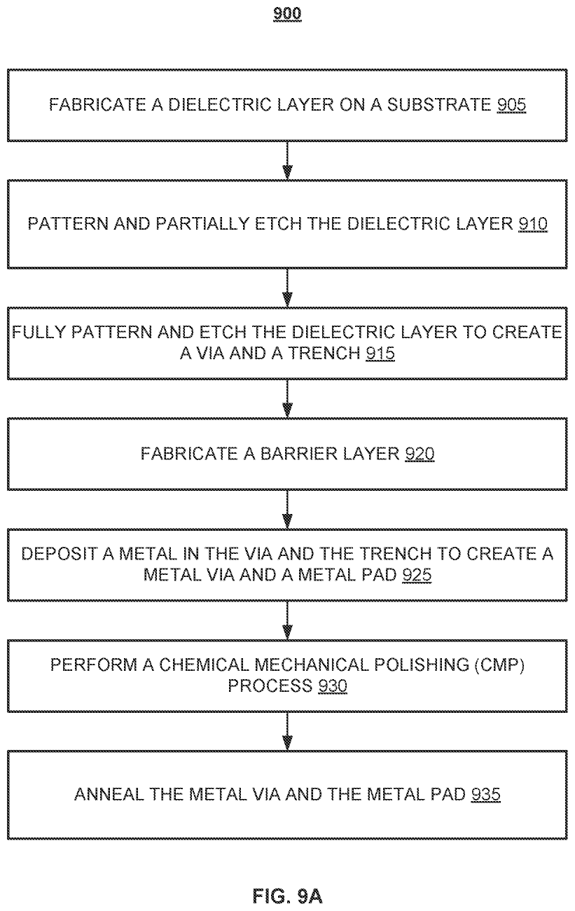

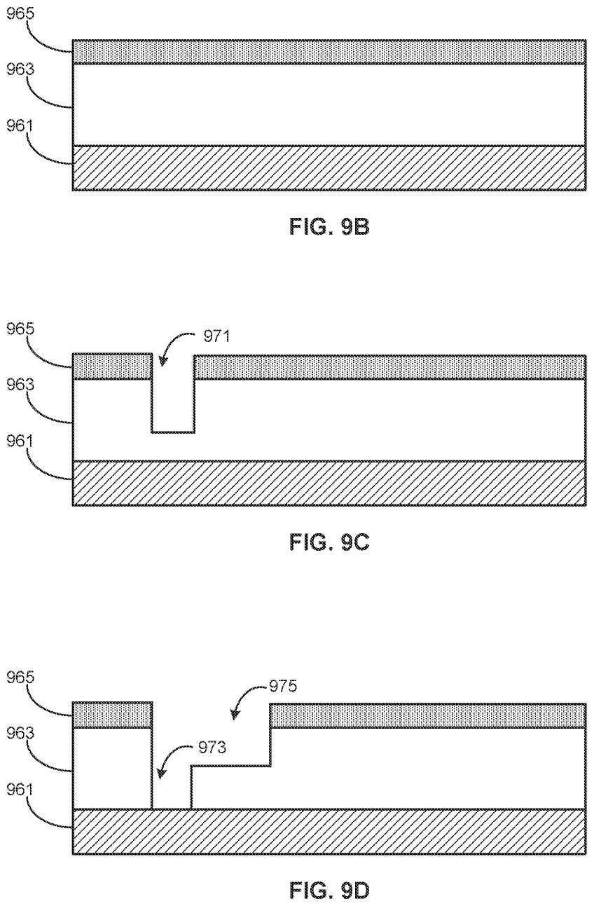

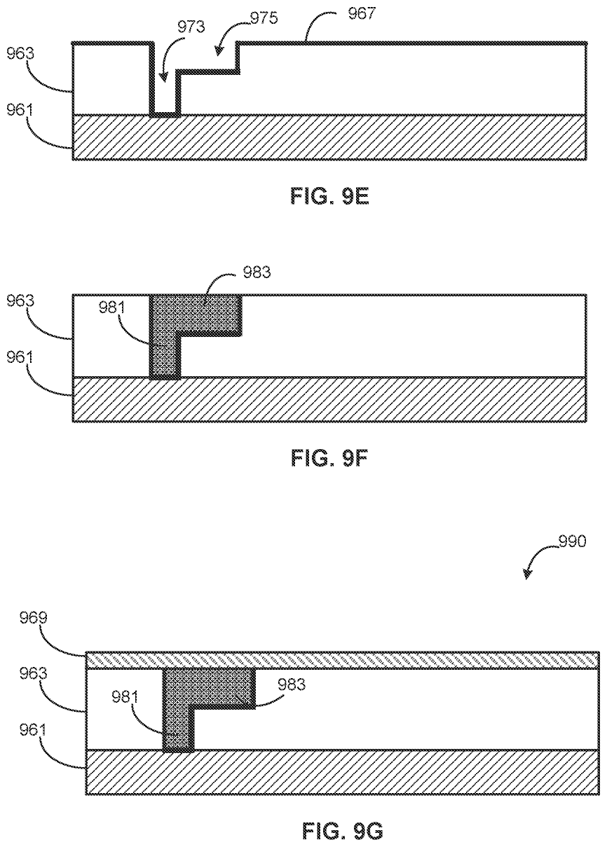

In some embodiments, fabricating the one or more first interconnect layers may involve performing one or more operations described in connection with FIG. 8 iteratively to fabricate a suitable number of interconnect layers. In some embodiments, a via layer and a metal layer may be fabricated in a dual-damascene fabrication process (e.g., process 900 of FIG. 9A). For example, a dielectric layer may be deposited on a substrate. The dielectric layer may then be patterned and filled by metal deposition. Metal vias and metal pads may be fabricated during the same metal deposition and patterning process.

At 720, an RRAM device may be fabricated on the one or more first interconnect layers. The RRAM device may be fabricated on a metal pad and/or a metal via of the top interconnect layer of the one or more first interconnect layers. For example, the RRAM device may be fabricated on the metal pad 321c of the metal layer 321 as described in connection with FIG. 4D above.

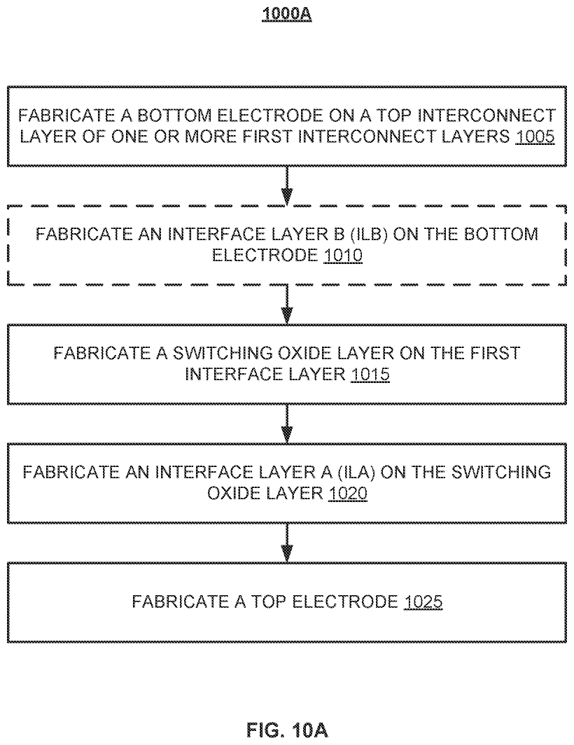

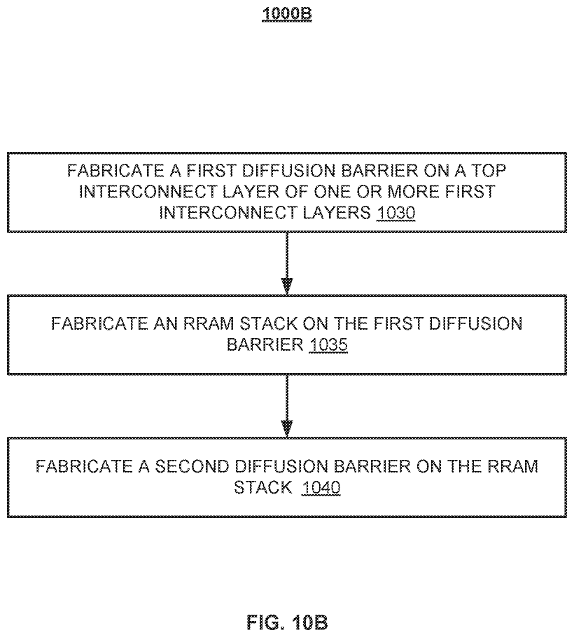

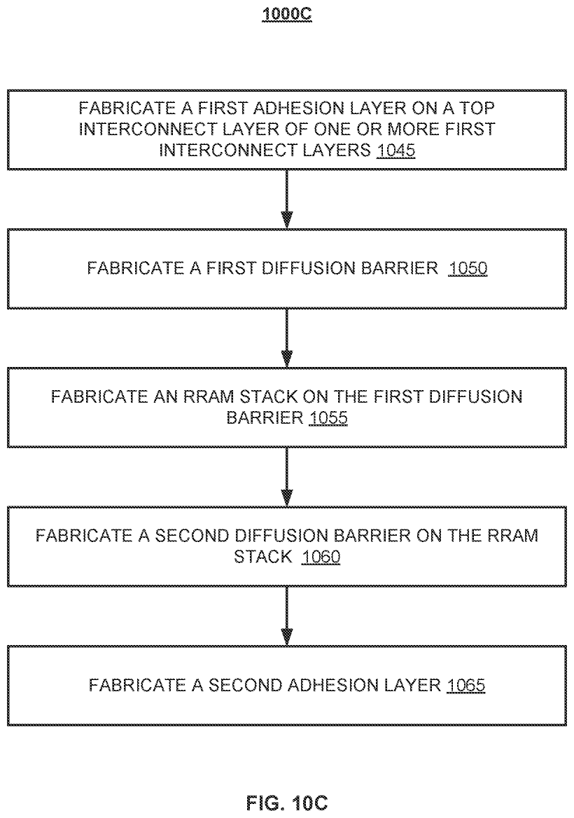

Fabricating the RRAM device may involve fabricating a bottom electrode, a switching oxide layer, a top electrode, one or more interface layers, one or more diffusion barriers, one or more adhesion layers, and/or any other suitable components. The switching oxide layer may be fabricated between the bottom electrode and the top electrode. In some embodiments, an interface layer may be fabricated between the switching oxide layer and the top electrode. Additionally, an interface layer may be fabricated between the bottom electrode and the switching oxide layer. In some embodiments, one or more diffusion barriers may be fabricated beneath the bottom electrode and/or on the top electrode. In some embodiments, one or more adhesion layers may be fabricated between the RRAM device and the interconnect layers adjacent to the RRAM device. The RRAM device may be fabricated by performing one or more operations as described in connection with FIGS. 10A-10C below.

At 730, one or more second interconnect layers may be fabricated on the RRAM device. The one or more second interconnect layers may be, for example, the one or more second interconnect layers 310b as described in connection with FIGS. 3A-4F above. Each of the second interconnect layers may include one or more metal pads and/or metal vias as described herein. A pair of neighboring metal layers may be connected via a via layer fabricated between the neighboring metal layers. As an example, a metal via of a bottom interconnect layer of the second interconnect layers (e.g., metal via 312c of FIG. 3A) may be fabricated on the RRAM device. One or more other metals vias of the bottom interconnect layer of the second interconnect layers (e.g., metal vias 312a and 312b of FIG. 3A) may be fabricated on the top interconnect layer of the first interconnect layers (e.g., metal layer 321 of FIG. 3A). Fabricating the second interconnect layers may involve annealing each of the second interconnect layers in a forming gas. As the second interconnect layers are fabricated on the RRAM device, the RRAM device is also annealed during the fabrication of the second interconnect layers. In some embodiments, fabricating the one or more second interconnect layers may involve performing one or more operations described in connection with FIGS. 8 and/or 9A iteratively.

FIG. 8 is a flowchart illustrating an example process 800 for fabricating one or more interconnect layers in accordance with some embodiments of the present disclosure.

At 810, a via layer including one or more metal vias may be fabricated. To fabricate the via layer, a first dielectric layer of a first dielectric material may be fabricated at 811. For example, a layer of the first dielectric material (e.g., Si₃N₄, SiO₂, etc.) may be deposited using suitable deposition techniques, such as chemical vapor deposition (CVD), atomic layer deposition (ALD), plasma-enhanced chemical vapor deposition (PECVD), sputtering, etc.

At 813, the first dielectric layer may be patterned to create one or more vias. The first dielectric layer may be patterned using any suitable dry and wet etching techniques.

At 815, one or more suitable metallic materials may be deposited in the vias and patterned to fabricate one or more metal vias. For example, the first vias may be filled by depositing Cu, Al, W, and/or any other suitable metal utilizing CVD, PVD and/or any other suitable deposition technique.

At 817, an annealing process is carrier out. For example, the first via layer may be annealed in forming gas ambient at suitable temperatures (e.g., 350-450° C.) for a suitable period of time (e.g., 15-30 minutes). The forming gas may include a mixture of nitrogen (N₂) and hydrogen (H₂) in a suitable ratio (e.g., 95:5, 90:10, etc.).

At 820, a metal layer including one or more metal pads may be fabricated on the via layer. To fabricate the metal layer, a second dielectric layer of a second dielectric material may be fabricated at 821. For example, a layer of the second dielectric material (e.g., Si₃N₄) may be deposited on the via layer using suitable deposition techniques, such as chemical vapor deposition (CVD), sputtering, etc.

At 823, the second dielectric layer may be patterned to create one or more trenches. The second dielectric layer may be patterned using any suitable dry and wet etching techniques.

At 825, one or more suitable metallic materials may be deposited in the trenches and patterned to fabricate one or more metal pads. For example, the second vias may be filled by depositing Cu, Al, W, and/or any other suitable metal utilizing CVD and/or any other suitable deposition technique.

At 827, an annealing process is carrier out. For example, the metal layer may be annealed in forming gas ambient at suitable temperatures (e.g., 350-450° C.) for a suitable period of time (e.g., 15-30 minutes). The forming gas may include a mixture of nitrogen (N₂) and hydrogen (H₂) in a suitable ratio (e.g., 95:5, 90:10, etc.).

The process 800 may be performed iteratively to fabricate a suitable number of interconnect layers. For example, the process 800 may loop back to 810 after performing block 820 and may fabricate a second via layer on the metal layer fabricated at 820. In particular, a third dielectric layer of a third dielectric material may be fabricated. The third dielectric layer may be patterned to create one or more third vias. One or more suitable metallic materials may be deposited in the third vias to fabricate one or more metal vias. Annealing process may then be carried out. A second metal layer may be fabricated on the second via layer in some embodiments. Additional layers of via layers and/or metal layers may be fabricated by performing blocks 810 and/or 820 iteratively.

FIG. 9A is a flow chart illustrating an example process 900 for fabricating an interconnect structure including a metal via and a metal pad in one process. FIGS. 9B-9G illustrate cross-sectional views of structures for fabricating an interconnect structure 990 by implementing process 900 in accordance with some embodiments of the present disclosure.

As shown, process 900 may start at 905 by fabricating a dielectric layer on a substrate. The substrate may be and/or include one or more transistors, interconnect layers, etc. Depositing the dielectric layer may involve depositing one or more interlayer dielectrics (ILDs), such as SiO₂, Si₃N₄, Al₂O₃, etc. For example, as shown in FIG. 9B, a dielectric layer 963 may be fabricated on a substrate 961. In some embodiments, a resist 965 may be fabricated on the dielectric layer 963.

At 910, the dielectric layer may be patterned and partially etched, which means the dielectric layer is partially etch in depth. For example, as shown in FIG. 9C, a via 971 may be fabricated by partially etching the dielectric layer 963 and the resist 965.

At 915, the partially etched dielectric layer may be fully etched to create a via and a trench or a pad. Here filly etched means the dielectric is fully etched in depth while maintaining an etching profile for via and trench due to the conformal etching. For example, as shown in FIG. 9D, a via 973 and a trench 975 may be created by etching the partially etched dielectric layer 963 and the resist 965.

At 920, a barrier layer may be fabricated. For example, as shown in FIG. 9E, a barrier layer 967 (e.g., a layer including Ta or TaN) may be deposited on the fully etched dielectric layer and over the sidewalls of the via 973 and the trench 975.

At 925, a metal may be deposited to create a metal via and a metal pad. For example, a thin Cu seed layer may be deposited by physical vapor deposition (PVD) followed by the electroplating of Cu, which fills the via and the trench. The metal deposition may also create one or more metal wires. As shown in FIG. 9E, a metal may be deposited (e.g., by plating) in the via 973 and the trench 975 to create a metal via 981 and a metal pad 983, respectively.

At 930, a chemical mechanical polishing (CMP) process is performed. For example, the metal via 981, the metal pad 983, and metal wires (not shown) may be patterned and processed in the CMP process to remove excess Cu and planarize the surface, as shown in FIG. 9F. In some embodiments, as shown in FIG. 9G, a capping layer 969 (e.g., a SiN layer) may be deposited.

At 935, the metal via and the metal pad may be annealed. For example, the interconnect structure 990 of FIG. 9G may be annealed at the annealing temperatures (e.g., 350-450° C.) in a forming gas flow (e.g., a mixture of N₂ and H₂) for a suitable period of time (e.g., 15-30 minutes).

FIGS. 10A and 10B are flowcharts illustrating example processes 1000A and 1000B for fabricating an RRAM device in accordance with some embodiments of the present disclosure.

At block 1005, a bottom electrode may be fabricated on a top interconnect layer of one or more first interconnect layers. The inner interconnect layer may include one or more metal vias and/or metal contacts. Fabricating the bottom electrode may involve depositing, on a metal pad or metal via of the interconnect layer, one or more layers of one or more nonactive metals, such as Pt, Pd, Jr, etc. utilizing a physical vapor deposition (PVD) technique, a chemical vapor deposition (CVD) technique, a sputtering deposition technique, an atomic layer deposition (ALD) technique, and/or any other suitable deposition technique. In some embodiments, fabricating the bottom electrode may involve depositing one or more layers of Pt.

In some embodiments, fabricating the bottom electrode may include depositing a metal nitride on a metal pad or metal via of the interconnect layer. The metal nitride may include, for example, tantalum nitride, titanium nitride, etc.

At block 1010, an interface layer B (ILB) may be fabricated on the bottom electrode. Fabricating the ILB may involve depositing a first material on the bottom electrode to form a film of the first material. The first material may be more chemically stable than the transition metal oxide(s) in the switching oxide layer as described below. In some embodiments, the first material may include Al₂O₃, MgO, Y₂O₃, La₂O₃, etc. In one implementation, fabricating the ILB may involve depositing a continuous layer of the first material. In another implementation, fabricating the ILB may involve depositing a layer of the first material having a suitable thickness to form the first discontinuous film. For example, fabricating the ILB may involve depositing the first material to a thickness between about 0.2 nm and about 1 nm. The first discontinuous film may be deposited utilizing PVD, CVD, ALD, and/or any other suitable deposition technique.

At block 1015, a switching oxide layer may be fabricated on the interface layer B. The switching oxide layer may include one or more transition metal oxides. The transition metal oxides may include, for example, TaOₓ, HfOₓ, TiOₓ, NbOₓ, ZrOₓ, etc. In some embodiments, during the fabrication of the switching oxide layer, one or more portions of the transition metal oxides may be deposited on the bottom electrode through one or more of the first pores. The switching oxide layer may be deposited utilizing PVD, CVD, ALD, and/or any other suitable deposition technique.

At block 1020, an interface layer A (ILA) may be fabricated on the switching oxide layer. Fabricating the ILA may involve depositing a second material on the switching oxide layer. The second material may be more chemically stable than the transition metal oxide(s) in the switching oxide layer. In some embodiments, the second material may include Al₂O₃, MgO, Y₂O₃, La₂O₃, etc. In one implementation, fabricating the ILA may involve depositing a continuous layer of the second material. In another implementation, fabricating the ILA may involve depositing a layer of the second material having a suitable thickness to form a discontinuous film. The ILA may be deposited utilizing PVD, CVD, ALD, and/or any other suitable deposition techniques.

At block 1025, a top electrode may be fabricated on the interface layer B. Fabricating the top electrode may involve depositing one or more suitable metallic materials that are electrically conductive and reactive to the switching oxide in the switching oxide layer, such as Ta, Hf, Ti, TiN, TaN, etc. The top electrode may include one or more alloys. The top electrode may be fabricated utilizing PVD, CVD, ALD, and/or any other suitable deposition technique.

Referring to FIG. 10B, process 1000B may be implemented to fabricate the RRAM device 600a as described in connection with FIG. 6A.

At 1030, a first diffusion barrier may be fabricated on a top interconnect layer of one or more first interconnect layers. Fabricating the first diffusion barrier may involve depositing a layer of a first material that exhibits suitable thermal and chemical stability, conductivity, and adhesion, such as TaN, TiN, etc.

At 1035, an RRAM stack may be fabricated on the first diffusion barrier. The RRAM stack may include a bottom electrode, a top electrode, a switching oxide layer between the bottom electrode and the top electrode, and one or more interface layers. The RRAM stack may be the RRAM devices 500a and/or 500b as described in connection with FIGS. 5A and 5B. Fabricating the RRAM stack may involve performing one or more operations as described in connection with FIG. 10A.

At 1040, a second diffusion barrier may be fabricated on the RRAM stack. Fabricating the second diffusion barrier may involve depositing a second material that may exhibit suitable thermal and chemical stability, conductivity, and adhesion, such as TaN, Ta, TiN, etc.

Referring to FIG. 10C, process 1000C may be implemented to fabricate the RRAM device 600b of FIG. 6B and/or the RRAM device 600c of FIG. 6C.

At 1045, a first adhesion layer may be fabricated on a top interconnect layer of one or more first interconnect layers. The first interconnect layers may include one or more via layers and/or metal layers. The first interconnect layers may be the first interconnect layer(s) 310a of FIG. 3. Fabricating the first adhesion layer may involve fabricating one or more layers of Ti, Ta, Ti₄O₇, etc. by PVD, CVD, and other suitable deposition technologies.

At 1050, a first diffusion barrier may be fabricated on the first adhesion layer. Fabricating the first diffusion barrier may involve depositing a layer of a first material that exhibits suitable thermal and chemical stability, conductivity, and adhesion, such as TaN, TiN, etc.

At 1055, an RRAM stack may be fabricated on the first diffusion barrier. The RRAM stack may include a bottom electrode (e.g., a bottom electrode), a top electrode (e.g., a top electrode), a switching oxide layer between the bottom electrode and the top electrode, and one or more interface layers. The RRAM stack may be the RRAM devices 500a and/or 500b as described in connection with FIGS. 5A and 5B. Fabricating the RRAM stack may involve performing one or more operations as described in connection with FIG. 10A.

At 1060, a second diffusion barrier may be fabricated on the RRAM stack. Fabricating the second diffusion barrier may involve depositing a second material that may exhibit suitable thermal and chemical stability, conductivity, and adhesion, such as TaN, Ta, TiN, etc.

At 1065, a second adhesion layer may be fabricated on the second diffusion barrier. Fabricating the second adhesion layer may involve fabricating one or more layers of Ti, Ta, Ti₄O₇, etc.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
one or more first interconnect layers fabricated on a transistor;
an RRAM device fabricated on the one or more first interconnect layers, wherein the RRAM device comprises:
a bottom electrode connected to a drain region of the transistor via the one or more first interconnect layers, wherein the bottom electrode is fabricated on a metal pad or a metal via of a top interconnect layer of the one or more first interconnect layers;
a switching oxide layer comprising at least one transition metal oxide;
a top electrode; and
a first interface layer fabricated between the top electrode and the switching oxide layer, wherein the first interface layer comprises a first material that is more chemically stable than the at least one transition metal oxide; and
one or more second interconnect layers fabricated on the RRAM device.

2. The apparatus of claim 1, wherein the one or more first interconnect layers comprise a first via layer comprising a first plurality of metal vias, wherein a first metal via of the first plurality of metal vias is connected to a source region of the transistor, wherein a second metal via of the first plurality of metal vias is connected to a gate of the transistor, and wherein a third metal via of the first plurality of metal vias is connected to a drain region of the transistor, and wherein the bottom electrode of the RRAM device is connected to the drain region of the transistor via the third metal via.

3. The apparatus of claim 2, wherein the first metal via is connected to a wordline, wherein the second metal via is connected to a select line, and wherein the top electrode of the RRAM device is connected to a bitline.

4. The apparatus of claim 2, wherein the one or more first interconnect layers further comprise a first metal layer comprising a plurality of metal pads, wherein the bottom electrode of the RRAM device is connected to the drain region of the transistor via one of the metal pads and the third metal via.

5. The apparatus of claim 2, wherein the one or more second interconnect layers comprise a plurality of metal layers connected through one or more via layers, wherein each of the plurality of metal layers comprises one or more metal pads, wherein each of the via layers comprises one or more metal vias, and wherein a pair of neighboring metal layers of the plurality of metal layers are connected through one of the via layers.

6. The apparatus of claim 1, wherein the first material comprises at least one of Al₂O₃, MgO, Y₂O₃, or La₂O₃.

7. The apparatus of claim 1, further comprising a first diffusion barrier fabricated between the one or more first interconnect layers and the bottom electrode of the RRAM device.

8. The apparatus of claim 7, wherein the first diffusion barrier comprises at least one of TaN, Ta, or TiN.

9. The apparatus of claim 7, further comprising a second diffusion barrier fabricated between the top electrode of the RRAM device and the one or more second interconnect layers.

10. The apparatus of claim 9, wherein the second diffusion barrier comprises at least one of TaN, Ta, or TiN.

11. The apparatus of claim 9, further comprising a first adhesion layer fabricated between the one or more first interconnect layers and the first diffusion barrier, wherein the first adhesion layer comprises a layer of at least one of Ti, Ta, or Ti₄O₇.

12. The apparatus of claim 11, further comprising a second adhesion layer fabricated between the second diffusion barrier and the one or more second interconnect layers, wherein the second adhesion layer comprises a layer of at least one of Ti, Ta, or Ti₄O₇.

13. The apparatus of claim 1, wherein the RRAM device further comprises a second interface layer fabricated between the bottom electrode of the RRAM device and the switching oxide layer of the RRAM device, wherein the second interface layer comprises a layer of a second material that is more chemically stable than the at least one transition metal oxide, wherein the second material comprises at least one of Al₂O₃, MgO, Y₂O₃, or La₂O₃.

14. A method, comprising:
fabricating an RRAM device on one or more first interconnect layers, comprising:
fabricating a bottom electrode on a metal via or a metal pad of a top interconnect layer of the one or more first interconnect layers;
fabricating a switching oxide layer comprising at least one transition metal oxide;
fabricating a first interface layer on the switching oxide layer, wherein the first interface layer comprises a first material that is more chemically table than the at least one transition metal oxide; and
fabricating a top electrode on the first interface layer; and
fabricating one or more second interconnect layers on the RRAM device.

15. The method of claim 14, wherein fabricating the one or more second interconnect layers comprises fabricating, on the RRAM device, a metal pad or a metal via of a bottom interconnect layer of the one or more second interconnect layers.

16. The method of claim 15, wherein fabricating the one or more second interconnect layers comprises annealing the one or more second interconnect layers and the RRAM device in a forming gas.

17. The method of claim 14, wherein fabricating the one or more first interconnect layers comprises fabricating a first via layer, wherein a first metal via of the first via layer is connected to a source region of a transistor, wherein a second metal via of the first via layer is connected to a gate of the transistor, and wherein a third metal via of the first via layer is connected to a drain region of the transistor, and wherein the bottom electrode of the RRAM device is connected to the drain region of the transistor through the third metal via.

18. The method of claim 17, wherein the one or more first interconnect layers further comprise a first metal layer comprising a plurality of metal pads, wherein the bottom electrode of the RRAM device is connected to the drain region of the transistor via one of the metal pads and the third metal via.

19. The method of claim 14, further comprising fabricating a first diffusion barrier between the one or more first interconnect layers and the bottom electrode of the RRAM device, wherein the first diffusion barrier comprises at least one of TaN, Ta, or TiN.

20. The method of claim 14, further comprising fabricating a second diffusion barrier between the top electrode of the RRAM device and the one or more second interconnect layers, wherein the second diffusion barrier comprises at least one of TaN, Ta, or TiN.
